(19) United States
(12) Patent Application Publication
(10) Pub. No.: US 2019/0051573 A1
(43) Pub. Date: Feb. 14, 2019

(54) SEMICONDUCTOR DEVICE

(71) Applicant: FUJI ELECTRIC CO., LTD., Kawasaki (JP)

(72) Inventor: Hideaki KATAKURA, Matsumoto (JP)

(73) Assignee: FUJI ELECTRIC CO., LTD., Kawasaki (JP)

(21) Appl. No.: 16/017,363

(22) Filed: Jun. 25, 2018

(30) Foreign Application Priority Data
Aug. 9, 2017 (JP) 2017-153888

(51) Int. Cl. H01L 23/31; H01L 23/525; H01L 23/532; H01L 23/29

(52) U.S. Cl. CPC H01L 23/3171; H01L 23/291; H01L 23/53271; H01L 23/5256

(57) ABSTRACT

A semiconductor device includes a first insulating film on a semiconductor substrate; a fuse on the first insulating film, including first second terminal pads, a blowing strip having a width smaller than the first and second terminal pads, extending from the first terminal pad to the second terminal pad, a first connecting portion connecting the first terminal pad and the blowing strip, and a second connecting portion connecting the second terminal pad and the blowing strip, and a second insulating film covering the first insulating film and the fuse. The first and second connecting portions are asymmetric with respect to a reference plane passing through the middle point of the blowing strip, orthogonal to the extending direction of the blowing strip and normal to the principal surface of the semiconductor substrate.

### CROSS REFERENCE TO RELATED APPLICATIONS

This application is based upon and claims the benefit of priority from the prior Japanese Patent Application No. P2017-153888 filed on Aug. 9, 2017, the entire contents of which are incorporated herein by reference.

### BACKGROUND

### 1. Technical Field

The present invention relates to a semiconductor device having a fuse trimming circuit.

### 2. Related Art

A fuse trimming circuit is used to switch functions and to adjust characteristics in a semiconductor integrated circuit (IC). For example, based on results of the wafer test, polysilicon fuses to be trimmed in the fuse trimming circuit are checked according to the items to be adjusted, and the polysilicon fuses are trimmed (blown). A crack sometimes occurs in the interlayer insulating film covering the polysilicon fuse when the polysilicon fuse is under blowing by Joule heating ascribable to the current flowing through the polysilicon fuse. When the crack expands, the moisture-tolerant performance of the semiconductor device such as the semiconductor integrated circuit may degrade, and the reliability of the semiconductor device may deteriorate.

JP H59-956 A discloses the semiconductor device in which the silicon nitride film is provided between the fuse and the field oxide film in order to eliminate heat-induced damage of the field oxide film when the fuse has blown. In JP 2006-286858 A, the side spacer is formed on the side wall portion of the fuse element, and the insulating film covering the side spacer is formed, thereby ensuring a distance between the polysilicon and the coated insulating film formed above. JP 2002-76121 A discloses the semiconductor device including the fuse element having the blowing strip with a width smaller than that of the connecting portion in order to prevent damage to the adjacent fuse element and the lower layer.

However, in the technique described in JP H59-956 A, the step of forming the silicon nitride film is necessary, and in the technique described in JP 2006-286858 A, the step of processing the insulating film to a tapered shape is necessary. For this reason, in the techniques described in JP H59-956 A and JP 2006-286858 A, the manufacturing cost may increase instead of reducing the damage to the insulating film and improving the reliability of the fuse. In the technique described in JP 2002-76121 A, since the coupling site between the blowing strip and the connecting portion of the fuse element has a right-angled shape, if the fuse element is blown by an electric current instead of a laser beam, the similar cracks may simultaneously occur in the interlayer insulating film of each coupling portion. Therefore, when the fuse element described in JP 2001-76121 A is blown with the electric current, the respective cracks may join together and expand.

### SUMMARY

An aspect of the present invention inheres in a semiconductor device encompassing (a) a first insulating film on a semiconductor substrate, (b) a fuse on a principal surface of the first insulating film, including first and second terminal pads, a blowing strip having a width smaller than the first and second terminal pads, extending from the first terminal pad to the second terminal pad, a first connecting portion connecting the first terminal pad and the blowing strip and a second connecting portion connecting the second terminal pad and the blowing strip, and (c) a second insulating film covering the first insulating film and the fuse. In the semiconductor device pertaining to the aspect of the present invention, the planar patterns of the first and second connecting portions viewed from a direction normal to a principal surface of the semiconductor substrate, are asymmetric with respect to a reference plane. Here, the reference plane passes through the middle point of the blowing strip, being orthogonal to an extending direction of the blowing strip and normal to the principal surface of the semiconductor substrate.

### BRIEF DESCRIPTION OF DRAWINGS

FIG. 1A is a plan view illustrating an example of a semiconductor device according to an embodiment of the present invention;

FIG. 1B is a cross-sectional view taken along line Ib-Ib of FIG. 1A;

FIG. 2A is a plan view illustrating an example of a semiconductor device according to a first comparative example;

FIG. 2B is a cross-sectional view taken along line IIb-IIb of FIG. 2A;

FIG. 3 is a plan view illustrating an example of a semiconductor device according to a second comparative example;

FIG. 4 is a plan view for explaining how a crack occurs in the semiconductor device according to the embodiment of the present invention;

FIG. 5 is a plan view illustrating a semiconductor device according to a first modification of the embodiment of the present invention;

FIG. 6 is a plan view illustrating a semiconductor device according to a second modification of the embodiment of the present invention;

FIG. 7 is a plan view illustrating a semiconductor device according to a third modification of the embodiment of the present invention;

FIG. 8 is a circuit diagram of a resistance adjustment circuit in which the semiconductor device according to the third modification of the embodiment of the present invention is applied; and

FIG. 9 is a cross-sectional view illustrating a configuration of a series circuit illustrated in FIG. 8.

### DETAILED DESCRIPTION

Exemplary embodiments of the invention will be described below in detail with reference to the drawings. The same or similar reference numerals are used to designate the same or similar elements throughout the drawings to avoid duplicated description. Since the drawings are schematic, a relationship between a thickness and plane dimensions, a ratio of thickness of each layer, and the like may be different from the actual one. Portions having different dimensional relations and ratios may also be included between drawings. The embodiments described hereinafter exemplify devices and methods for embodying the technical idea of the invention, and the technical idea of the invention does not specify the material, shape, structure, or arrangement of the elements described below.

The terms relating to directions, such as “upper,” “lower,” “top,” and “bottom” in the following description will be used for the purpose of explanation and will not limit the technical idea of the invention. For example, when a subject target having upper and lower ends is rotated by 90°, the upper and lower ends of the subject target is expressed as left and right ends of the target, respectively. When the subject target is rotated by 180°, the upper end and the lower end is changed into the lower end and the upper end, respectively.

### Semiconductor Device of the Embodiment

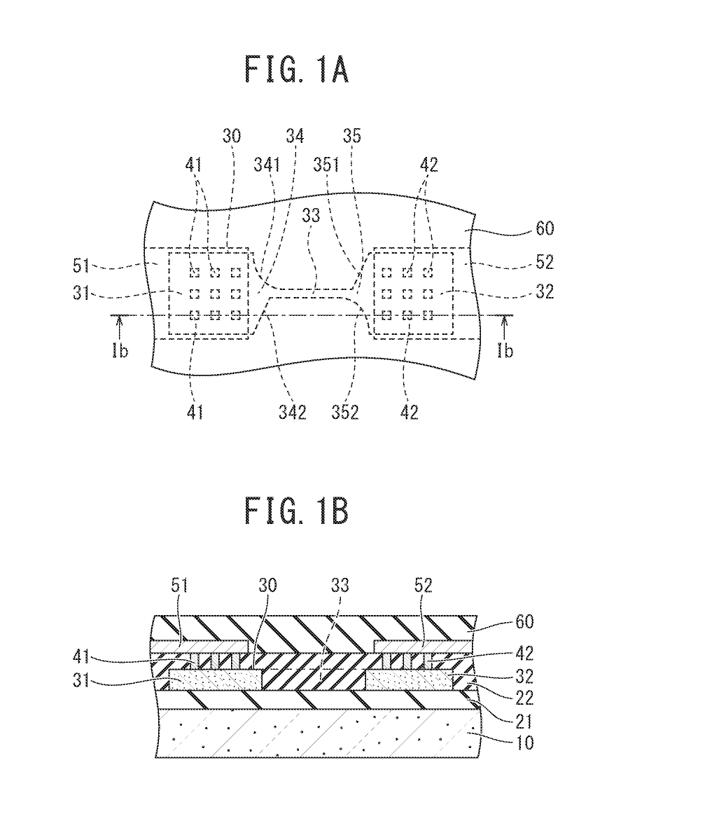

As illustrated in FIGS. 1A and 1B, a semiconductor device according to an embodiment of the present invention includes a first insulating film (under-layer insulating film) 21 disposed on a principal surface of a semiconductor substrate 10, a fuse 30 disposed on the first insulating film 21, a second insulating film (interlayer insulating film) 22 covering the first insulating film 21 and the fuse 30, a protection film (passivation film) 60. The fuse 30 is a resistor element having a first terminal pad (voltage-applying pad) 31 and a second terminal pad (GND pad) 32 and a belt-shaped blowing strip 33 extending from the voltage-applying pad 31 to the GND pad 32. The fuse 30 further includes a first connecting portion 34 connecting between the voltage-applying pad 31 and the blowing strip 33 and a second connecting portion 35 connecting between the GND pad 32 and the blowing strip 33. As can be seen from FIG. 1A, the planar patterns of the first connecting portion 34 and the second connecting portion 35 are asymmetric with respect to a reference plane normal to the principal surface of the semiconductor substrate 10 including the longitudinal center line of the blowing strip 33. Additionally, the planar patterns of the first connecting portion 34 and the second connecting portion 35 are also asymmetric with respect to a reference plane passing through the middle point of the blowing strip 33, which is normal to the principal surface of the semiconductor substrate 10 and orthogonal to the extending direction of the blowing strip 33.

Here, the “semiconductor substrate 10” is not limited to a base material obtained by cutting an ingot pulled up by the Czochralski method (CZ method), the floating zone method (FZ method) or the like into a wafer shape. The “semiconductor substrate 10” includes not only a raw substrate as the base material but also a multilayered structure such as an epitaxial growth substrate epitaxially grown on the top surface of a raw substrate or a Silicon-On-Insulator (SOI) substrate in which an insulating film is in contact with the bottom surface of a raw substrate. That is, the “semiconductor substrate 10” is a generic name as a superordinate concept which may include various multilayered structures with the raw substrate, a semiconductor region defining an active area in a part of the multilayered structure, and the like besides the raw substrate.

For the semiconductor substrate 10, for example, a semiconductor wafer made of silicon (Si) or the like can be adopted as the base material. For the first insulating film 21, a silicon oxide (SiO₂) film, a silicon nitride (Si₃N₄) film, or a composite film of the SiO₂ film and the Si₃N₄ film can be adopted. The first insulating film 21 may be a field oxide film used for the local oxidation of silicon (LOCOS) technique or the shallow trench isolation (STI) technique, an oxide film continuously formed to the field oxide film, or the like. An insulator region, such as an STI isolation region or the like, may be included in the upper portion of the semiconductor substrate 10. For example, a thickness of the first insulating film 21 may be about 0.4 micrometer to one micrometer.

The semiconductor device according to the embodiment of the present invention may implement a part of an integrated circuit. That is, the semiconductor device of the embodiment may implement a part of a control circuit for a vertical power transistor at the output stage or the like, for example. On the semiconductor substrate 10, it is also possible to integrate the control circuit and the vertical power transistor such as an insulated gate bipolar transistor (IGBT), or the like.

In FIG. 1A, the voltage-applying pad 31 and the GND pad 32 are schematically illustrated as a rectangular flat plate shape, respectively, but the shape is not limited to a rectangular shape. The blowing strip 33 has a width smaller than an edge of each rectangular of the voltage-applying pad 31 and the GND pad 32. For example, the blowing strip 33 has a length of about two micrometers, a width of about several hundred nanometers to one micrometer, and a thickness of about 0.1 micrometer to 0.5 micrometer. As illustrated in FIG. 1B, the voltage-applying pad 31 and the GND pad 32 have a thickness equal to that of the blowing strip 33.

The first connecting portion 34 and the second connecting portion 35 are formed in such a manner that each width becomes smaller and smaller as getting closer to the blowing strip 33. The planar patterns of the first connecting portion 34 and the second connecting portion 35 are asymmetric with respect to the horizontal center line along the extending direction of the blowing strip 33. That is, as illustrated in FIG. 1A, a first side wall 341 of the first connecting portion 34 and a second side wall 351 of the second connecting portion 35 corresponding to the first side wall 341 have different curvatures from each other in the planar patterns. Similarly, the first opposite side wall 342 of the first connecting portion 34 and the second opposite side wall 352 of the second connecting portion 35 corresponding to the side wall 342 have different curvatures from each other in the planar patterns. As a result, the planar patterns of the first connecting portion 34 and the second connecting portion 35 are also asymmetric with respect to the vertical center line, which is orthogonal to the horizontal center of the blowing strip 33.

More specifically, the first side wall 341 that is the upper side wall of the first connecting portion 34 in the orientation illustrated in FIG. 1A is an arc-shaped vertically curved surface continuing from the side wall of the voltage-applying pad 31 to the side wall of the blowing strip 33. The “vertically curved surface” means that the direction of the generating line of the curved surface defining the upper side wall is normal to the principal surface of the semiconductor substrate 10 illustrated in FIG. 1B. On the other hand, the second side wall 351 of the second connecting portion 35 corresponding to the first side wall 341 connects the GND pad 32 and the blowing strip 33 with a vertically flat surface. In FIG. 1A, the end portion of the vertically flat surface forming the second side wall 351 is viewed as a straight line. The side wall 342 on the lower side of the first connecting portion 34 in FIG. 1A is the vertically flat surface continuing from the side wall of the voltage-applying pad 31 to the side wall of the blowing strip 33. The side wall 352 at the lower side of the second connecting portion 35 in the orientation illustrated in FIG. 1A is the arc-shaped vertically curved surface continuing from the side wall of the GND pad 32 to the side wall of the blowing strip 33. For convenience sake, in FIG. 1A, the side wall 342 is illustrated as the vertically flat surface and the side wall 352 is illustrated as the vertically curved surface. However, these side walls are not limited to the “vertically flat surface” or the “vertically curved surface”. The side wall 342 and the second side wall 351 may be inclined flat surfaces (tapered planes), and the first side wall 341 and the side wall 352 may be inclined curved surfaces (quadratic surfaces) similar to the “curved wave reflector” at seawall. In particular, the “flat surface” with regard to the side wall of the fuse 30 is not limited to a complete plane, since the side wall may be rounded or tapered due to manufacturing processes. The “flat surface” means that when viewing from a direction parallel to the surface, the end section is approximately straight. Similarly, the first side wall 341 and the side wall 352 may be a polyhedral plane composed of multiple planes, each having different normal direction.

The curve of the end section of the first side wall 341 of the first connecting portion 34 exposed in FIG. 1A is curved so as to be convex toward the lower left direction. As illustrated in FIG. 1A, at a position near the intersection of the first side wall 341 and the blowing strip 33, the upper right end of the first opposite side wall 342 of the first connection portion 34 intersects the side wall of the blowing strip 33. The straight line defining the edge of the end section of the side wall 342 exposed in FIG. 1A is inclined with respect to the extending direction of the blowing strip 33. Similarly, the curve of the end section of the side wall 352 of the second connecting portion 35 exposed in FIG. 1A is curved so as to be convex toward the upper right direction. The other second side wall 351 of the second connecting portion 35 intersects the side wall of the blowing strip 33 at a position near the intersection of the side wall 352 and the blowing strip 33. The straight line defining the edge of the end section of the second side wall 351 exposed in FIG. 1A is inclined with respect to the extending direction of the blowing strip 33. It should be noted that the main portion of the fuse 30 has a three-dimensional structure having two-fold rotational symmetry with respect to a symmetry axis passing through the middle point of the blowing strip 33 along the direction normal to the principal surface of the semiconductor substrate 10.

For a material of the fuse 30, a polysilicon in which impurities are doped with high concentration, a polycide or a metallic material may be used. As a silicide for implementing the polycide, a composition including titanium silicide (TiSi₂), cobalt silicide (CoSi₂), tungsten silicide (WSi₂) or the like can be exemplified. Furthermore, tantalum silicide (TaSi₂), molybdenum silicide (MoSi), nickel silicide (NiSi), or the like may be used for the silicide implementing the polycide. For the metallic material, refractory metals such as tungsten (W), molybdenum (Mo), platinum (Pt), titanium (Ti), or the like can be exemplified. In addition to the refractory metals, aluminum (Al), gold (Au), copper (Cu) can be exemplified.

For the second insulating film 22, an SiO₂ film, a phospho-silicate glass (PSG) film, a boro-silicate glass (BSG) film or a boro-phospho-silicate glass (BPSG) film, or a composite film thereof can be adopted. The second insulating film 22 may be an insulating film of an organosilicon-based compound or the like by a chemical vapor deposition (CVD) method using a tetraethoxysilane (TEOS) gas or the like. The thickness of the second insulating film 22 is, for example, about 0.7 micrometer to one micrometer. Therefore, the second insulating film 22 is disposed so as to cover the top surface of the first insulating film 21, the side surface and the top surface of the fuse 30, and to bury the fuse 30 between the first insulating film 21 and the second insulating film 22.

Wiring layers 51 and 52 are disposed on the top surface of the second insulating film 22. For a materials of the wiring layers 51 and 52, for example, Al—Si, Al—Si—Cu, Al—Cu or the like can be adopted, and also a copper-interconnect by damascene process or the like may be used. The wiring layer 51 is connected to the voltage-applying pad 31 via a plurality of contact plugs 41 made of the refractory metal such as W, Mo, Ti for example. Similarly, the wiring layer 52 is connected to the GND pad 32 via a plurality of contact plugs 42 made of the refractory metal such as W, Mo, Ti for example. The contact plugs 41, 42 may be formed by the same material as the wiring layers 51, 52.

For the protective film 60, for example, a Si₃N₄ film can be adopted for surface passivation of the subject integrated circuit. For example, at any appropriate sites not illustrated in FIGS. 1A and 1B, the wiring layers 51 and 52 are electrically connected to target upper-level interconnections implementing the subject integrated circuit or the like, via contact holes (not shown) formed in the protective film 60 so as to expose respectively the corresponding portions of the top surfaces of the target upper-level interconnections.

By connecting the GND pad 32 of the fuse 30 to an electrical ground potential GND via the wiring layer 52, and applying a pulse voltage to the voltage-applying pad 31 via the wiring layer 51, a current flows from the voltage-applying pad 31 to the GND pad 32 through the blowing strip 33. In the blowing strip 33 which has the width narrower than that of the voltage-applying pad 31 and the GND pad 32, the current density is higher than that of the voltage-applying pad 31 and the GND pad 32. Then, the blowing strip 33 is heated and blown by Joule heat. When the blowing strip 33 is blown, the blown region where the blowing strip 33 has been existed previously in the inner side of the second insulating film 22 becomes substantially hollow. Thus, the voltage-applying pad 31 and the GND pad 32 are electrically isolated.

### First Comparative Example

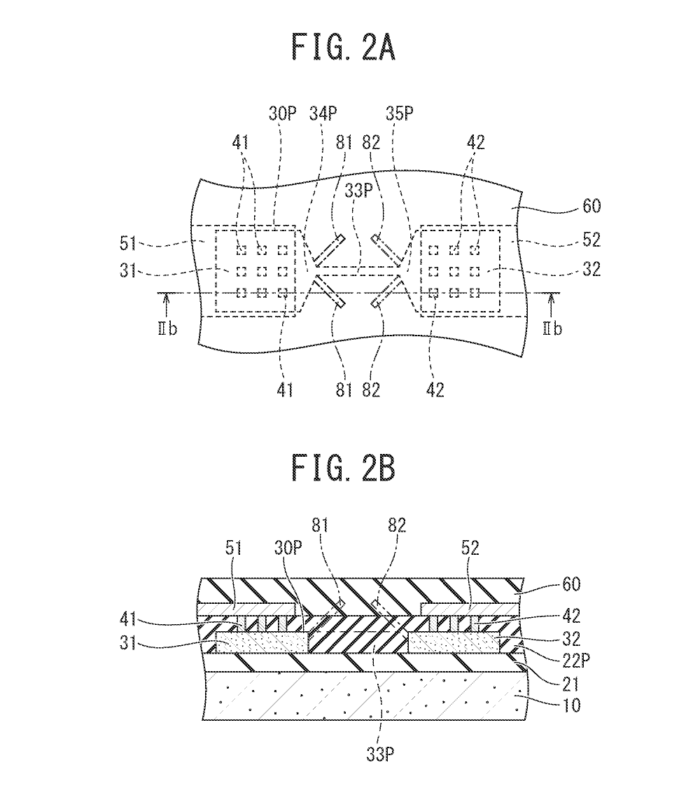

Here, a semiconductor device according to a first comparative example will be described. In the semiconductor device according to the first comparative example, as illustrated in FIGS. 2A and 2B, each side wall of the first connecting portion 34P and the second connecting portion 35P is a flat surface. That is, viewed in a planar pattern, the fuse 30P has four corner portions linearly intersecting each other at the intersection points between the side wall of the blowing strip 33P and each side walls of the first connecting portion 34P and the second connecting portion 35P. When the fuse 30P is blown at the occasion of fuse trimming, since the side walls of the first connecting portion 34P and the second connecting portion 35P are linearly expanded, a stress based on the difference of the thermal expansion coefficients between the second insulating film 22P and the fuse 30P concentrates at the corner portions of the blowing strip 33P. Therefore, in the second insulating film 22P, there is a possibility that cracks 81 may occur obliquely upward from the two corners between the first connecting portion 34P and the blowing strip 33P. Similarly, at the occasion of fuse trimming, there is a possibility that cracks 82 may occur obliquely upward from the two corners between the second connecting portion 35P and the blowing strip 33P in the second insulating film 22P.

When the shapes of the four corners of the blowing strip 33P of the fuse 30P are equal to each other, the cracks 81 and 82 may simultaneously occur due to the thermal expansion of the fuse 30P. That is, when the first connecting portion 34P and the second connecting portion 35P have a symmetrical topology with respect to a plane of symmetry, the plane of symmetry is orthogonal to the extending direction of the blowing strip 33P, the plane passing through the middle position of the blowing strip 33P, the cracks 81, 82 may simultaneously occur by the thermal expansion of the fuse 30P. The larger the sizes of the cracks 81 and 82, the greater the possibility that the humidity-tolerant behavior of the semiconductor device such as the semiconductor integrated circuit or the like will deteriorate. Then, the reliability of the semiconductor device may decrease. Therefore, it is required to suppress the enlargement of the cracks 81 and 82.

### Second Comparative Example

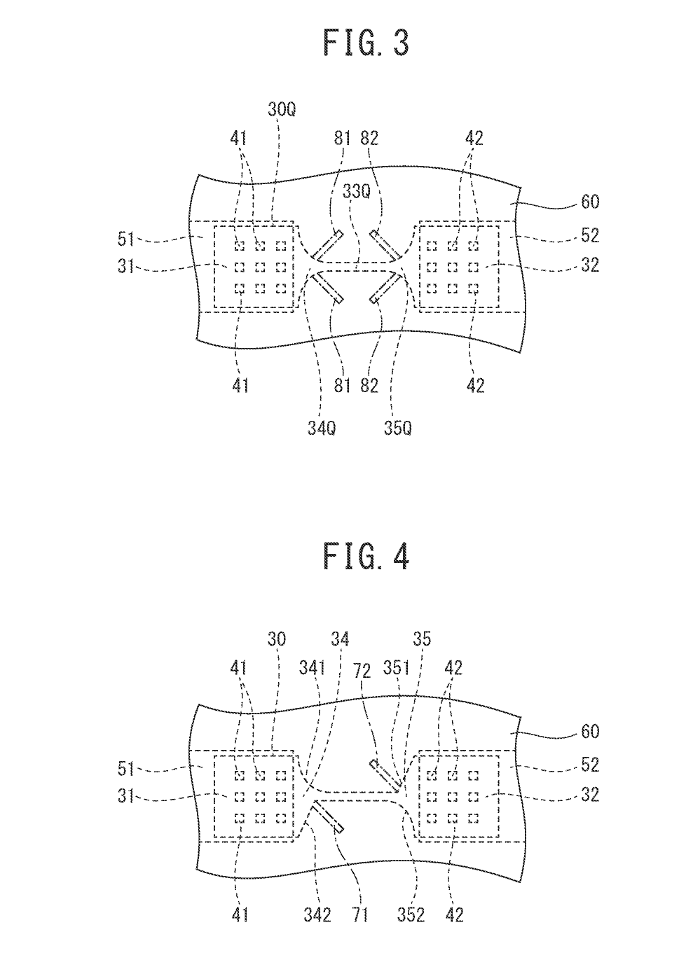

Next, a semiconductor device according to a second comparative example will be described. In the fuse 30Q of the semiconductor device according to the second comparative example, as illustrated in FIG. 3, each of the first connecting portion 34Q and the second connecting portion 35Q has arc-shaped side walls, viewed in a planar pattern. Compared to the first comparative example, the fuse 30Q of the second comparative example may relieve the concentration of stress due to thermal expansion during the fuse trimming, and the cracks may be less prone to occur. However, although the probability of occurrence decreases, there is a possibility that the crack 81 occurs on the side of the first connecting portion 34Q and the crack 82 occurs at the side of the second connecting portion 35Q, respectively. When the first coupling portion 34Q and the second coupling portion 35Q have a symmetrical topology with respect to a symmetrical plane passing through the middle position of the blowing strip 33Q and orthogonal to the extending direction of the blowing strip 33Q, there is still a possibility that the crack 81 and the crack 82 spontaneously occur. When the cracks 81 and 82 spontaneously occur, the cracks 81 and 82 may be joined each other and as a result, the large cracks may be generated, as in the first comparative example.

### Comparison with the First and Second Comparative Examples

In contrast, in the semiconductor device according to the embodiment of the present invention, the planar patterns of the first connecting portion 34 and the second connecting portion 35 is asymmetric with respect to a reference plane passing through the middle position of the blowing strip 33, which is orthogonal to the extending direction of the blowing strip 33 and normal to the principal surface of the semiconductor substrate 10.

Therefore, in the semiconductor device according to the embodiment, the timing at which cracks occur at the occasion of fuse trimming is controlled. Specifically, as illustrated in FIG. 4, in the planar pattern viewed from the top surface side, the second side wall 351 of the second connecting portion 35 has the linear, and the second side wall 351 has the corner portion linearly intersecting with the blowing strip 33. In the planar pattern viewed from the top surface side illustrated in FIG. 4, stress tends to concentrate at the corner portion that linearly intersects more than the corresponding arc-shaped first side wall 341, and a crack 72 is prone to occur in the second insulating film (not shown) during the fuse trimming. Similarly, since the side wall 342 of the first connecting portion 34 has a corner portion that linearly intersects with the blowing strip 33, stress tends to concentrate at the corner portion more than the corresponding arc-shaped side wall 352, and is susceptive to a crack 71.

When the cracks 71 and 72 occur in the second insulating film at earlier stage of the fuse trimming, the stress in the second insulating film is relieved by the occurrence of the cracks 71 and 72. Therefore, even if the cracks 71, 72 are generated when the fuse 30 is being blown, the occurrence probability of the cracks on the arc-shaped side walls 341, 352 is reduced. Furthermore, since the planar patterns of the first connecting portion 34 and the second connecting portion 35 are asymmetric, there is a low possibility that the cracks 71, 72 are joined each other in the extending direction of the blowing strip 33. As described above, in the semiconductor device according to the embodiment of the present invention, it is possible to suppress the expansion of cracks during fuse trimming by a simple method of adjusting the planar pattern of the fuse 30 and by preventing degradation of moisture-tolerant property of the semiconductor device, and therefore, reliability can be improved.

### (First Modification)

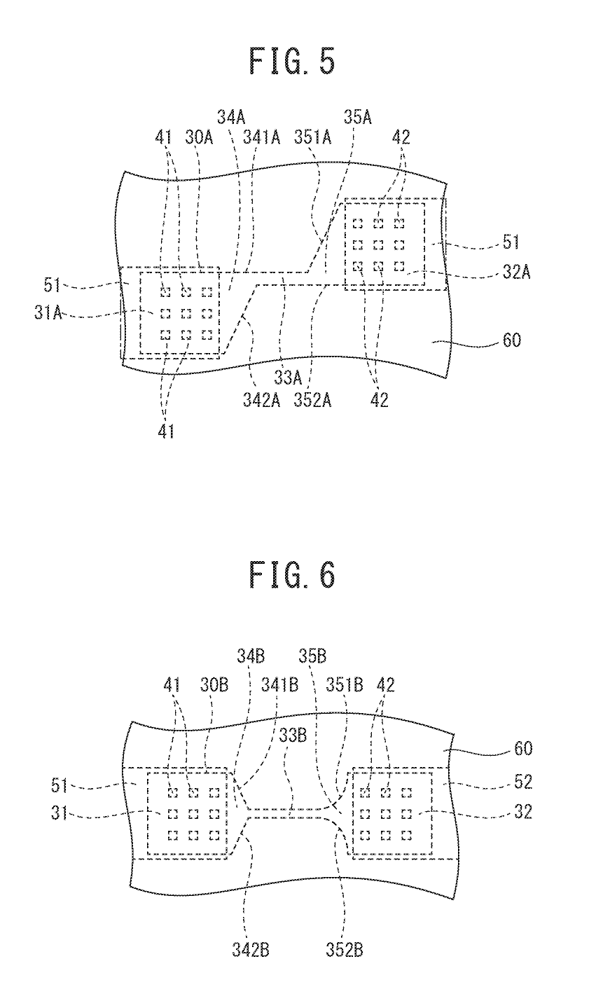

A semiconductor device according to a first modification of the embodiment of the present invention is different from the above-described embodiment in that, as illustrated in FIG. 5, in a direction orthogonal to the extending direction of the blowing strip 33A along the principal surface of the semiconductor substrate (not shown), a first terminal pad (voltage-applying pad) 31A and a second terminal pad (GND pad) 32A are arranged to be displaced from each other. The configurations, operations and effectiveness which are not described in the first modification are substantially the same as those in the embodiment, and duplicate description will be omitted.

A side wall of the voltage-applying pad 31A, a first side wall 341A of a first connecting portion 34A, and a side wall of the blowing strip 33A which are illustrated on the upper side of a fuse 30A in FIG. 5, are continuous and are merged into the same plane. That is, the side wall of the voltage-applying pad 31A, the first side wall 341A of the first connecting portion 34A, and the side wall of the blowing strip 33A are aligned on a straight line in a planar pattern. Similarly, a side wall of the GND pad 32A, a side wall 352A of the second connecting portion 35A, and a side wall of the blowing strip 33A which are illustrated on the lower side of the fuse 30A in FIG. 5, are continuous in the same plane. That is, the side wall of the GND pad 32A, the side wall 352A of the second connecting portion 35A, and the side wall of the blowing strip 33A are aligned on a straight line in a planar pattern. A straight line defining an edge of an end section of a first side wall 342A of the first connecting portion 34A is inclined with respect to the extending direction of the blowing strip 33A in such a manner that the width of the first connecting portion 34A becomes smaller as approaching the blowing strip 33A. Similarly, a straight line defining an edge of an end section of the second side wall 351A of the second connecting portion 35A is inclined with respect to the extending direction of the blowing strip 33A in such a manner that the width of the second connecting portion 35A becomes smaller as approaching the blowing strip 33A.

The first side wall 341A, which is linearly continuous with the upper side wall of the blowing strip 33A, and the side wall 352A, which is linearly continuous with the lower side wall of the blowing strip 33A, remarkably relieve the concentration of stress in the second insulating film (not shown). And therefore, the relax of the stress in the second insulating film can decrease the probability of occurrence of cracks. Therefore, even if cracks are generated from the side walls 342A and 351A which have the corner portions linearly intersecting with the blowing strip 33A, the possibility that the cracks join together and expand in the extending direction of the blowing strip 33A may decrease. As described above, according to the semiconductor device pertaining to the first modification of the embodiment, it is possible to improve the reliability by suppressing the degradation of the moisture-tolerant property.

### (Second Modification)

A semiconductor device according to the second modification of the embodiment of the present invention is different from the above-described embodiment in that, as illustrated in FIG. 6, in planar patterns, a first connecting portion 34B has linear side walls 341B and 342B, and a second connecting portion 35B has arc-shaped side walls 351B and 352B. The configurations, operations and effectiveness which are not described in the second modification are substantially the same as those in the embodiment, and duplicate description will be omitted.

The side walls 341B, 342B of the first connecting portion 34B have corner portions linearly intersecting with the blowing strip 33B. Therefore, the stress concentrates higher on the second insulating film (not shown) on the sites of the side walls 341B, 342B than the sites of the arc-shaped side walls 351B, 352B, and there is a high possibility that cracks may occurs first at the sites of the side walls 341B, 342B. When the crack occurs first on the site of the first connecting portion 34B, the stress in the second insulating film is relaxed. Thus, the occurrence probability of the crack in the site of the second connecting portion 35B is decreased. Therefore, the possibility that the cracks join together and expand in the extending direction of the blowing strip 33A may decrease, and it is possible to improve the reliability by suppressing degradation of the moisture-tolerant property of the semiconductor device.

### (Third Modification)

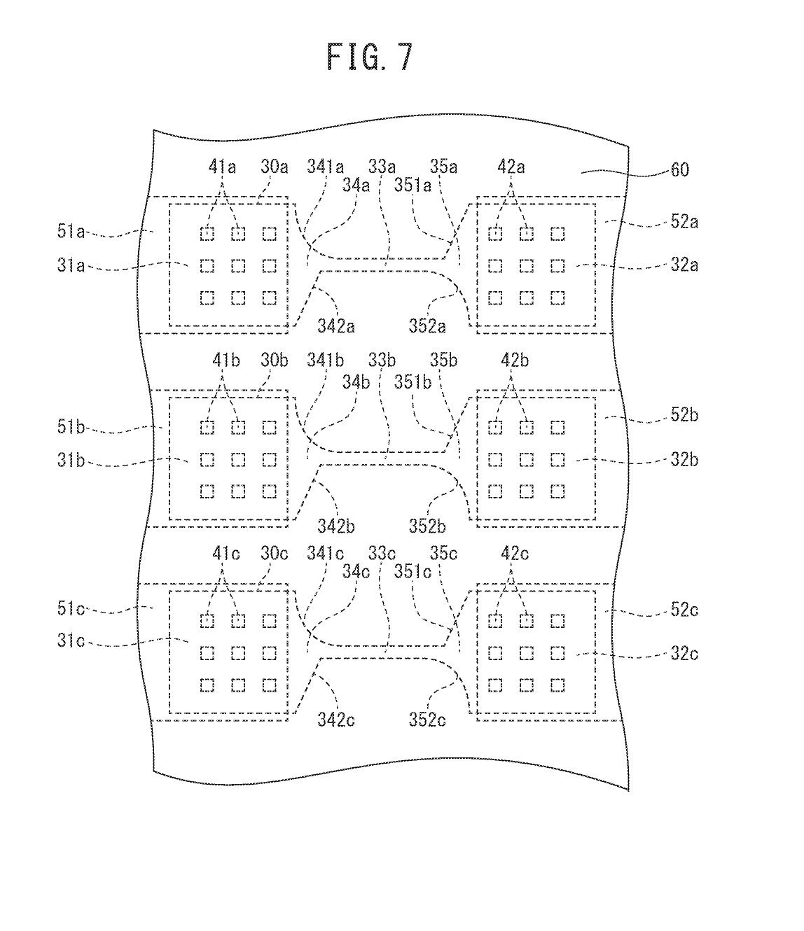

A semiconductor device according to a third modification of the embodiment of the present invention is different from the above-described embodiment in that, as illustrated in FIG. 7, a plurality of fuses 30a, 30b, 30c each having the same configuration as the fuse 30 of the semiconductor device according to the above-described embodiment, are provided. Although three fuses 30a to 30c are illustrated in FIG. 7, a number of the fuses may be two or four or more. The configurations, operations and effectiveness which are not described in the third modification are substantially the same as those in the embodiment, and duplicate description will be omitted.

The fuses 30a to 30c have the same dimensions and are periodically arranged so as to be adjacent to each other along the direction orthogonal to the extending direction of the blowing strips 33a, 33b, 33c on the principal surface of the semiconductor substrate (not shown). That is, each of the fuses 30a to 30c are arranged so as to coincide with automorphism of the structures of the fuses 30a to 30c, when the other fuses 30a to 30c move parallel to each other in the direction orthogonal to the extending direction of the blowing strips 33a to 33c.

As illustrated in FIG. 7, for example, the side wall 342a of the fuse 30a having a linear corner portion where a crack is prone to occur in the second insulating film (not shown) as compared with an arc-shaped side wall is disposed close to an arc-shaped first side wall 341b of the adjacent fuse 30b. That is, the side wall 342a of the fuse 30a and the first side wall 341b of the adjacent fuse 30b are asymmetric with respect to a reference plane which passes through a midpoint between the center of the blowing strip 33a of the fuse 30a and the center of the blowing strip 33b of the fuse 30b, and is parallel to the extending direction of the respective blowing strips 33a, 33b and normal to the principal surface of the semiconductor substrate.

Therefore, even if a crack is generated earlier from the side wall 342a site of the fuse 30a in the second insulating film, since the stress in the second insulating film is relaxed by the occurrence of crack, the occurrence possibility of crack on the first side wall 341b of the fuse 30b may decrease. Therefore, the possibility that the cracks join together and expand between the fuses 30a and 30b is decreased.

Similarly, for example, the second side wall 351c of the fuse 30c having a linear corner portion is disposed close to the arc-shaped side wall 352b of the adjacent fuse 30b. That is, the second side wall 351c of the fuse 30c and the side wall 352b of the adjacent fuse 30b are asymmetric with respect to a reference plane which passes through a midpoint between the center of the blowing strip 33b of the fuse 30b and the center of the blowing strip 33c of the fuse 30c, and is parallel to the extending direction of the respective blowing strips 33b, 33c and normal to the principal surface of the semiconductor substrate.

Therefore, in the semiconductor device according to the third modification of the embodiment of the present invention, the possibility that the cracks join together between the adjacent fuses 30a to 30c is decreased. That is, according to the semiconductor device pertaining to the third modification of the embodiment, it is possible to decrease the possibility that the cracks join together and expand not only in the extending direction of the blowing strips 33a, 33b, 33c but also in the direction orthogonal to the extending direction of the blowing strips 33a, 33b, 33c, and thus reliability can be improved by suppressing degradation of moisture-tolerant property.

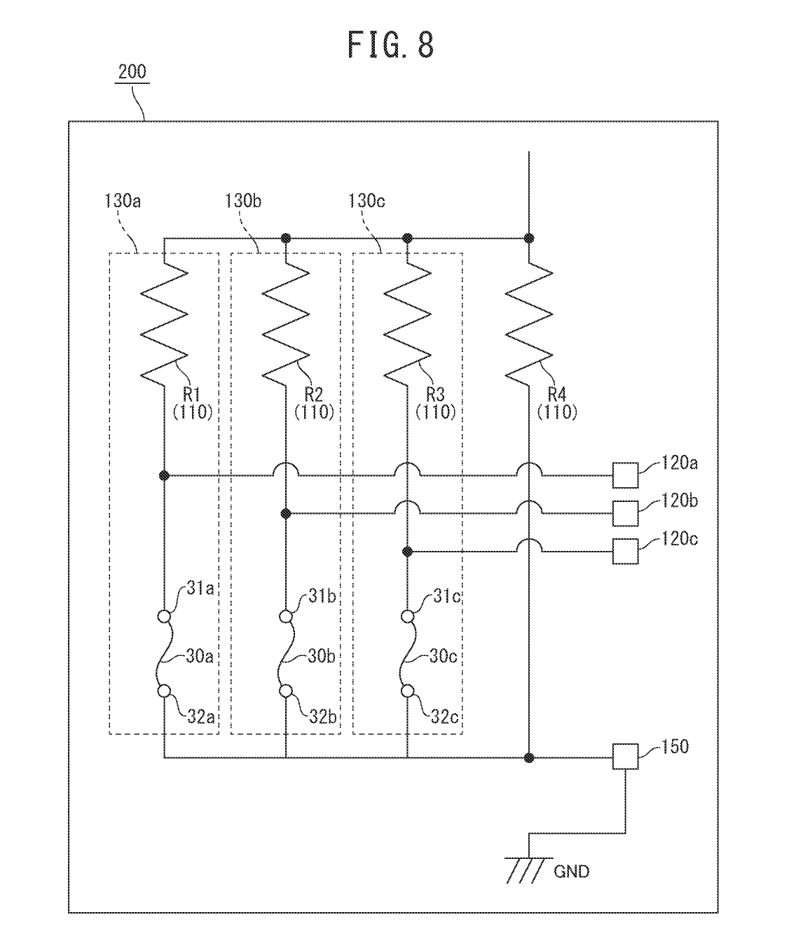

FIG. 8 is a circuit diagram of a resistance adjustment circuit to which the semiconductor device according to the third modification of the embodiment of the present invention is applied. The circuit diagram is a part of the control circuit of the vertical power transistor. The circuit diagram illustrates a part of the fuses 30a, 30b, 30c and the peripheral circuit of the fuses 30a, 30b, 30c.

Three series circuits 130a, 130b, 130c in which the fuses 30a to 30c are connected in series to the corresponding three resistors R1, R2, R3, respectively, are arranged in parallel. And a resistor R4 to which the fuses 30a to 30c are not connected is connected in parallel with the resistors R1, R2, R3. A first pad 120a for applying a blowing-voltage to the first blowing strip of the first fuse 30a is electrically connected to a first connection node between the first resistor R1 and the first voltage-applying pad (first terminal pad) 31a of the first fuse 30a. Similarly, a second pad 120b for applying a blowing-voltage to the second blowing strip of the second fuse 30b is electrically connected to a second connection node between the second resistor R1 and the second voltage-applying pad 31b of the second fuse 30b. Furthermore, a third pad 120c for applying a blowing-voltage to the third blowing strip of the third fuse 30c is electrically connected to a third connection node between the third resistor R1 and the third voltage-applying pad 31c of the third fuse 30b. The first GND pad (second terminal pad) 32a of the first fuse 30a is electrically connected to a common pad 150 for connection with a ground potential GND. Similarly, the second GND pad 32b of the second fuse 30b is electrically connected to the common pad 150, and the third GND pad 32c of the third fuse 30c is electrically connected to the common pad 150.

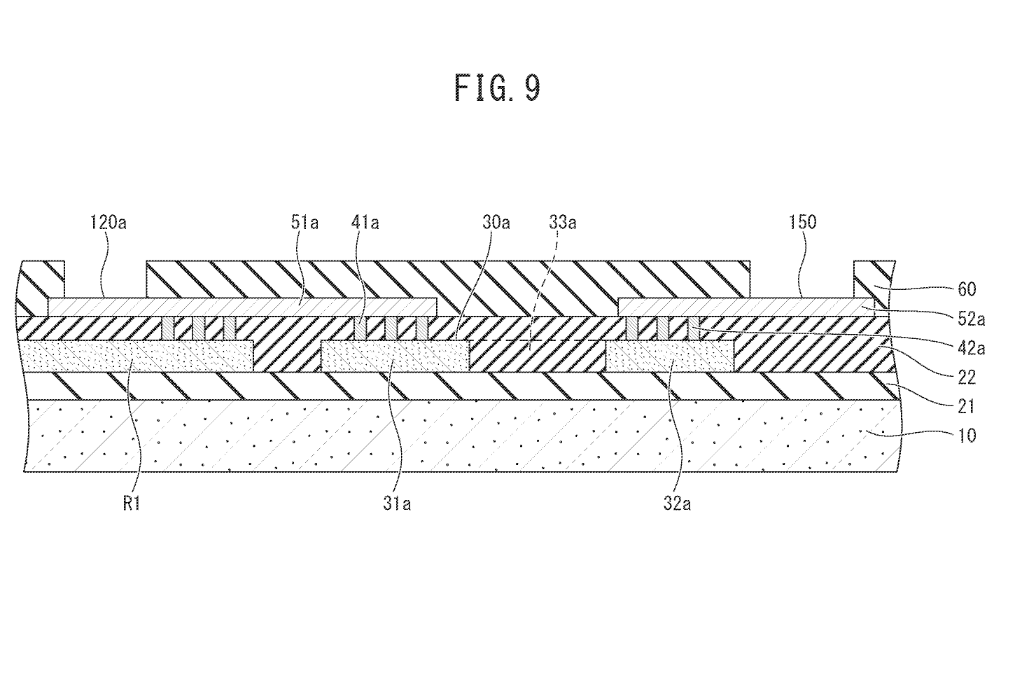

FIG. 9 is a cross-sectional view illustrating a configuration example of a part of the first resistor R1 in the resistor group 110 illustrated in FIG. 8, with the first pad 120a and the common pad 150.

The first resistor R1 is formed on the first insulating film 21. Further, the first pad 120a is a part of the wiring 51a and is exposed by an opening formed in the protective film 60. The common pad 150 is a part of the wiring 52a and is exposed by an opening formed in the protective film 60. Various circuit components of an integrated circuit (not shown) are formed on the semiconductor substrate 10.

Adjustment of a value of the resistance will be performed as follows. When the resistance value is out of the target at the occasion of characteristic check on the final stage of the wafer process, for example, the first fuse 30a is trimmed so as to have an appropriate resistance value. This trimming is performed by applying a voltage to the first fuse 30a via the first pad 120a, passing a current through the blowing strip 33a and blowing by Joule heat. The case of adjusting the resistance value has been described, but the invention is not limited to the disclosure recited in the third modification of the embodiment. For example, in order to select an optimum MOSFET, the fuses explained in the third modification of the embodiment may be used.

### Other Embodiments

Although a single embodiment and the first to third modifications of the embodiment of the present invention have been described above, it should not be understood that the description and drawings constituting apart of the above disclosure limit the present invention. From the above disclosure, various alternative embodiments, examples and operational techniques will be apparent to those skilled in the art. For example, it goes without saying that the present invention includes various embodiments, modifications and the like, which are not described here, such as configurations arbitrarily applied to each of the configurations described in the above embodiment and each modification. Therefore, the scope of the present invention is determined only by the technical features specifying the claimed invention prescribed by the claims, which is proper from the context and subject matters recited in the above description.

What is claimed is:

1. A semiconductor device comprising:
a first insulating film on a semiconductor substrate;
a fuse on the first insulating film, including,
first and second terminal pads,
a blowing strip having a width smaller than the first and second terminal pads, extending from the first terminal pad to the second terminal pad,
a first connecting portion connecting the first terminal pad and the blowing strip, and
a second connecting portion connecting the second terminal pad and the blowing strip; and
a second insulating film covering the first insulating film and the fuse; wherein
planar patterns of the first and second connecting portions viewed from a direction normal to a principal surface of the semiconductor substrate, are asymmetric with respect to a reference plane passing through the middle point of the blowing strip, the reference plane being orthogonal to an extending direction of the blowing strip and normal to the principal surface of the semiconductor substrate.

2. The semiconductor device of claim 1, wherein a line defining an end section of a first side wall of the first connecting portion and a line defining an end section of the first opposite side wall of the first connecting portion opposing to the first side wall have different curvatures from each other in the planar patterns.

3. The semiconductor device of claim 1, wherein a line defining an end section of a first side wall of the first connecting portion and a line defining an end section of a second side wall of the second connecting portion on a side opposing to the first side wall with respect to the reference plane have different curvatures from each other in the planar patterns.

4. The semiconductor device of claim 1, wherein a line defining an end section of a first side wall of the first connecting portion is an arc-shaped curve continuing from a side wall of the first terminal pad to a side wall of the blowing strip, and a line defining an end section of the first opposite side wall of the first connecting portion opposing to the first side wall is a straight line connecting an opposite side wall of the blowing strip from the side wall of the first terminal pad.

5. The semiconductor device of claim 1, wherein a line defining an end section of a first side wall of the first connecting portion is an arc-shaped curve continuing from a side wall of the first terminal pad to a side wall of the blowing strip, a line defining an end section of a second side wall of the second connection portion on a side opposing to the first side wall with respect to the reference plane is a straight line connecting the side wall of the blowing strip from a side wall of the second terminal pad.

6. The semiconductor device of claim 1, wherein a line defining an end section of a first side wall of the first connecting portion is a straight line connecting a side wall of the first terminal pad and a side wall of the blowing strip, and a line defining an end section of a second side wall of the second connecting portion opposing to the first side wall with respect to the reference plane is an arc-shaped curve connecting from a side wall of the second terminal pad to the side wall of the blowing strip.

7. The semiconductor device of claim 1, wherein the fuse is made of polysilicon, and the second insulating film is made of a silicon oxide film.
